(19) United States
(12) Patent Application Publication
(10) Pub. No.: US 2025/0176347 A1
(43) Pub. Date: May 29, 2025

(54) DEVICES AND METHODS PREVENTING DEGRADATION OF LIGHT EMITTING STRUCTURES

(71) Applicant: Lumileds LLC, San Jose, CA (US)

(72) Inventor: Hisashi MASUI, San Jose, CA (US)

(73) Assignee: Lumileds LLC, San Jose, CA (US)

(21) Appl. No.: 19/038,301

(22) Filed: Jan. 27, 2025

Related U.S. Application Data
(63) Continuation of application No. PCT/US2023/028585, filed on Jul. 25, 2023.
(60) Provisional application No. 63/402,697, filed on Aug. 31, 2022.

(51) Int. Cl. H10H 29/855; H10H 29/01

(52) U.S. Cl. CPC H10H 29/8552; H10H 29/0363

(57) ABSTRACT

This specification discloses light emitting structures with light emitting devices, where the structures include a protective layer that blocks certain wavelengths of light from degrading particularly vulnerable elements of the light emitting structures. The protective layer may be a transparent UV blocking layer that prevents a substantial amount of UV light from reaching an adhesive layer that would otherwise yellow or degrade under UV exposure. The transparent UV blocking layer may be completely or largely transparent to visible light, so that a user of the light emitting structure can clearly view the visible light emitted or incident on the light emitting structures.

### CROSS REFERENCE TO RELATED APPLICATIONS

This application is a continuation of PCT Application PCT/US2023/028585 filed Jul. 25, 2023, which claims benefit of priority to U.S. provisional application No. 63/402,697 filed on Aug. 31, 2022. Both of the above applications are incorporated by reference in this application in their entirety.

### FIELD OF THE INVENTION

The invention relates generally to light emitting structures, particularly those with at least one protective layer preventing degradation of one or more components, and methods for fabricating such structures.

### BACKGROUND

Semiconductor light emitting diodes and laser diodes (collectively referred to herein as “LEDs”) are among the most efficient light sources currently available. The emission spectrum of an LED typically exhibits a single narrow peak at a wavelength determined by the structure of the device and by the composition of the semiconductor materials from which it is constructed. By suitable choice of device structure and material system, LEDs may be designed to operate at ultraviolet, visible, or infrared wavelengths.

LEDs may be combined with one or more wavelength converting materials (generally referred to herein as “phosphors”) that absorb light emitted by the LED and in response emit light of a longer wavelength. For such phosphor-converted LEDs (“pcLEDs”), the fraction of the light emitted by the LED that is absorbed by the phosphors depends on the amount of phosphor material in the optical path of the light emitted by the LED, for example on the concentration of phosphor material in a phosphor layer disposed on or around the LED and the thickness of the layer. Phosphor-converted LEDs may be designed so that all the light emitted by the LED is absorbed by one or more phosphors, in which case the emission from the pcLED is entirely from the phosphors. In such cases the phosphor may be selected, for example, to emit light in a narrow spectral region that is not efficiently generated directly by an LED. Alternatively, pcLEDs may be designed so that only a portion of the light emitted by the LED is absorbed by the phosphors, in which case the emission from the pcLED is a mixture of light emitted by the LED and light emitted by the phosphors. By suitable choice of LED, phosphors, and phosphor composition, such a pcLED may be designed to emit, for example, white light having a desired color temperature and desired color-rendering properties.

Such LEDs and pcLEDs may be arranged in arrays for use, for example, in direct-view displays (e.g. for storefronts or automotive vehicles), glasses and other eyewear, mobile devices, other such applications. This specification uses the term LED array to include arrays of LEDs, pcLEDs, or combinations of LEDs and pcLEDs. In light emitting structures emitting light through a transparent layer, certain elements used in the structures may themselves be exposed to ambient light, such as sunlight. This ambient light may degrade some of those elements, resulting in a color change of the light emitted or mechanical degradation. What is needed is a solution to prevent this degradation.

### SUMMARY

This specification discloses a light emitting structure with a protective layer that prevents ultraviolet (UV light) from reaching elements of the light emitting structure that are vulnerable to UV. The protective layer may be a transparent UV absorbing layer that blocks most UV light but allows visible light clearly through, so that the light emitted by the structure can be clearly seen by users.

The LED arrays disclosed herein may be advantageously employed in, for example, any of the devices and applications listed above in the Background section or below.

Other embodiments, features and advantages of the present invention will become more apparent to those skilled in the art when taken with reference to the following more detailed description of the invention in conjunction with the accompanying drawings that are first briefly described.

### BRIEF DESCRIPTION OF THE DRAWINGS

FIG. 1 shows a schematic cross-sectional view of an example pcLED.

FIGS. 2A and 2B show, respectively, cross-sectional and top schematic views of an array of pcLEDs.

FIG. 3A shows a schematic top view of an electronics board on which an array of pcLEDs may be mounted, and FIG. 3B similarly shows an array of pcLEDs mounted on the electronic board of FIG. 3A.

FIG. 4A shows a schematic cross sectional view of an array of pcLEDs arranged with respect to waveguides and a projection lens. FIG. 4B shows an arrangement similar to that of FIG. 4A, without the waveguides.

FIG. 5 schematically illustrates an example camera flash system comprising an adaptive illumination system.

FIG. 6 schematically illustrates an example display (e.g., AR/VR/MR) system.

FIGS. 7a-7b illustrates a light emitting structure with a transparent UV absorbing layer on an opposite side of the substrate from the LEDs. FIG. 7a depicts the cross-sectional view while FIG. 7b depicts a plan view.

FIGS. 8a-8b illustrates a light emitting structure with a transparent UV absorbing layer made of discrete regions. FIG. 8a depicts the cross-sectional view while FIG. 8b depicts a plan view.

FIG. 9 illustrates a light emitting structure with a transparent UV absorbing layer between the LEDs and the substrate.

FIG. 10 illustrates a light emitting structure with a transparent window and a transparent UV absorbing layer on the transparent window.

FIG. 11 illustrates a light emitting structure with a transparent window and a transparent UV absorbing layer on the transparent window, as well as a transparent UV absorbing layer disposed on the substrate.

FIG. 12 depicts transmission from the substrate side of a stack with a CPI film after various hours of sunlight exposure.

FIG. 13 depicts transmission from the film side of a stack with a CPI film after various hours of sunlight exposure.

FIG. 14 depicts transmission of a CPI film alone after various hours of sunlight exposure.

FIG. 15 depicts transmission of a CPI film on an epoxy layer after various hours of sunlight exposure.

### DETAILED DESCRIPTION

The following detailed description should be read with reference to the drawings, in which identical reference numbers refer to like elements throughout the different figures. The drawings, which are not necessarily to scale, depict selective embodiments and are not intended to limit the scope of the invention. The detailed description illustrates by way of example, not by way of limitation, the principles of the invention.

FIG. 1 shows an example of an individual pcLED 100 comprising a light emitting semiconductor diode structure 102 disposed on a substrate 104, and a phosphor layer 106 disposed on the LED. Light emitting semiconductor diode structure 102 typically comprises an active region disposed between n-type and p-type layers. Application of a suitable forward bias across the diode structure results in emission of light from the active region. The wavelength of the emitted light is determined by the composition and structure of the active region.

The LED may be, for example, a III-Nitride LED that emits blue, violet, or ultraviolet light. LEDs formed from any other suitable material system and that emit any other suitable wavelength of light may also be used. Other suitable material systems may include, for example, III-Phosphide materials, III-Arsenide materials, and II-VI materials.

Any suitable phosphor materials may be used, depending on the desired optical output from the pcLED.

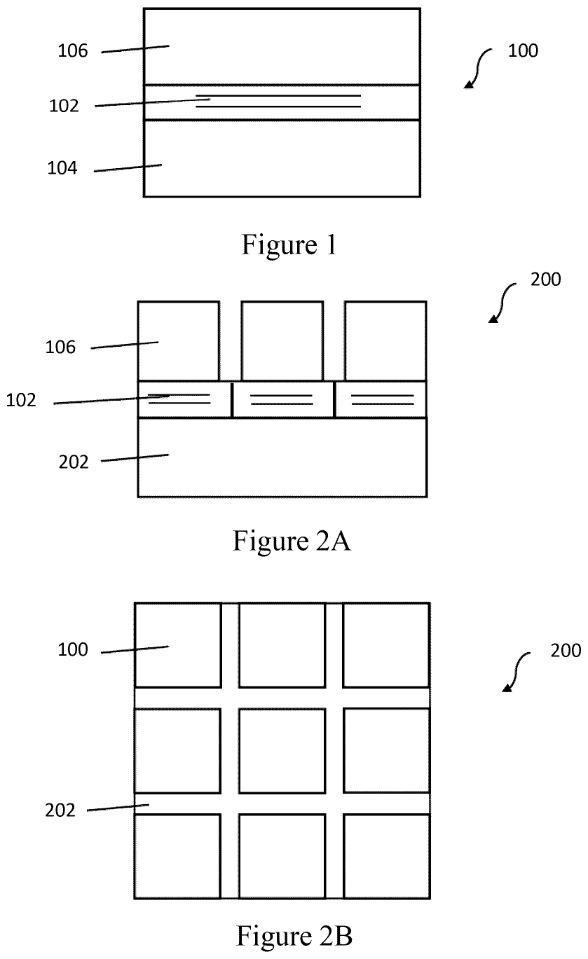

FIGS. 2A-2B show, respectively, cross-sectional and top views of an array 200 of pcLEDs 100 including phosphor pixels 106 disposed on a substrate 202. Such an array may include any suitable number of pcLEDs arranged in any suitable manner. In the illustrated example the array is depicted as formed monolithically on a shared substrate, but alternatively an array of pcLEDs may be formed from separate individual pcLEDs. Substrate 202 may optionally comprise CMOS circuitry for driving the LED, and may be formed from any suitable materials.

Although FIGS. 2A-2B, show a three-by-three array of nine pcLEDs, such arrays may include for example tens, hundreds, or any suitable number of LEDs. Individual LEDs (pixels) may have widths (e.g., side lengths) in the plane of the array of, for example, less than or equal to 1 millimeter (mm), less than or equal to 500 microns, or less than or equal to 100 microns. LEDs in such an array may be spaced apart from each other by streets or lanes having a width in the plane of the array of, for example, greater than a millimeter, less than or equal to a millimeter, or less than or equal to 500 microns. Although the illustrated examples show rectangular pixels arranged in a symmetric matrix, the pixels and the array may have any suitable shape.

The individual LEDs in an LED array may be individually addressable, may be addressable as part of a group or subset of the pixels in the array, or may not be addressable. Thus, light emitting diode arrays are useful for any application requiring or benefiting from fine-grained intensity, spatial, and temporal control of light distribution. These applications may include, but are not limited to, precise special patterning of emitted light from pixel blocks or individual pixels. Depending on the application, emitted light may be spectrally distinct, adaptive over time, and/or environmentally responsive. Such light emitting pixel arrays may provide pre-programmed light distribution in various intensity, spatial, or temporal patterns. The emitted light may be based at least in part on received sensor data and may be used for optical wireless communications. Associated electronics and optics may be distinct at a pixel, pixel block, or device level.

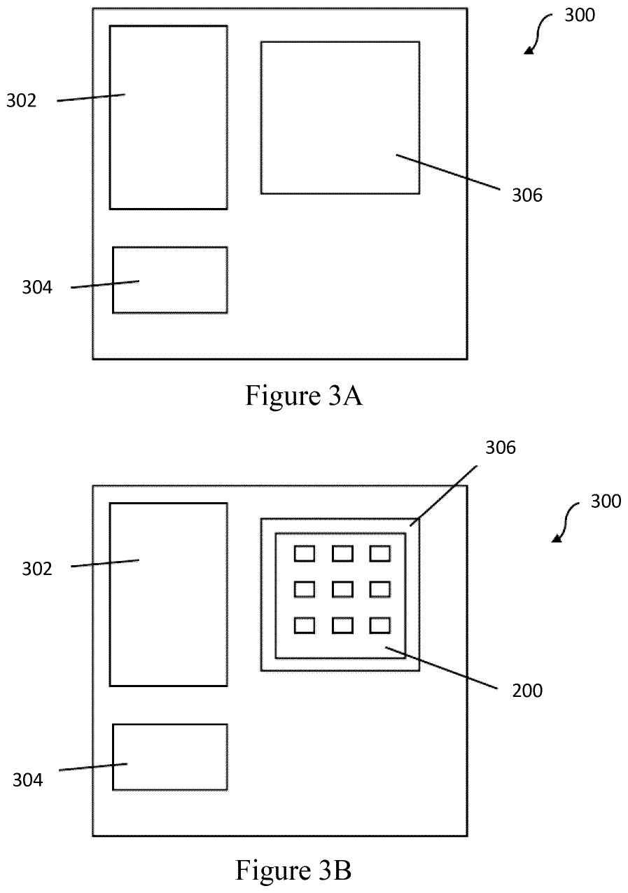

As shown in FIGS. 3A-3B, an LED array 200 may be mounted on an electronics board 300 comprising a power and control module 302, a sensor module 304, and an LED attach region 306. Power and control module 302 may receive power and control signals from external sources and signals from sensor module 304, based on which power and control module 302 controls operation of the LEDs. Sensor module 304 may receive signals from any suitable sensors, for example from temperature or light sensors. Alternatively, LED array 200 may be mounted on a separate board (not shown) from the power and control module and the sensor module.

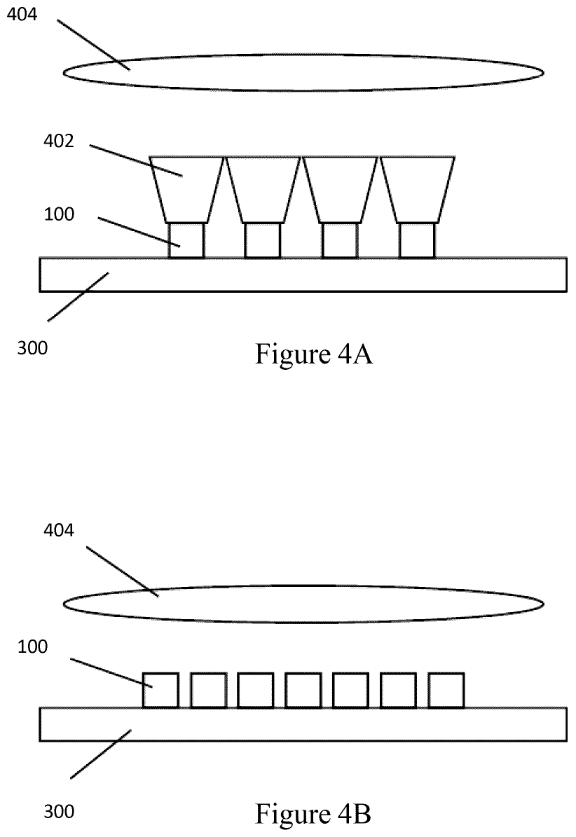

Individual LEDs and pcLEDs may optionally incorporate or be arranged in combination with a lens or other optical element located adjacent to or disposed on the phosphor layer. Such an optical element, not shown in the figures, may be referred to as a “primary optical element”. In addition, as shown in FIGS. 4A-4B an LED array 200 (for example, mounted on an electronics board 300) may be arranged in combination with secondary optical elements such as waveguides, lenses, or both for use in an intended application, for example as precollimators. In FIG. 4A, light emitted by pcLEDs 100 is collected by waveguides 402 and directed to projection lens 404. Projection lens 404 may be a Fresnel lens, for example. This arrangement may be suitable for use, for example, in interior automobile illumination, automobile headlights, and other exterior automobile illumination. In FIG. 4B, light emitted by pcLEDs 100 is collected directly by projection lens 404 without use of intervening waveguides. This arrangement may particularly be suitable when the LEDs or pcLEDs can be spaced sufficiently close to each other. Generally, any suitable arrangement of optical elements may be used in combination with the LED arrays described herein, depending on the desired application.

An array of independently operable LEDs may be used in combination with a lens, lens system, or other optical system (e.g., as described above) to provide illumination that is adaptable for a particular purpose. For example, in operation such an adaptive lighting system may provide illumination that varies by color and/or intensity across an illuminated scene or object and/or is aimed in a desired direction. A controller can be configured to receive data indicating locations and color characteristics of objects or persons in a scene and based on that information control LEDs in an LED array to provide illumination adapted to the scene. Such data can be provided for example by an image sensor, or optical (e.g. laser scanning) or non-optical (e.g. millimeter radar) sensors. Such adaptive illumination is increasingly important for automotive and illumination applications.

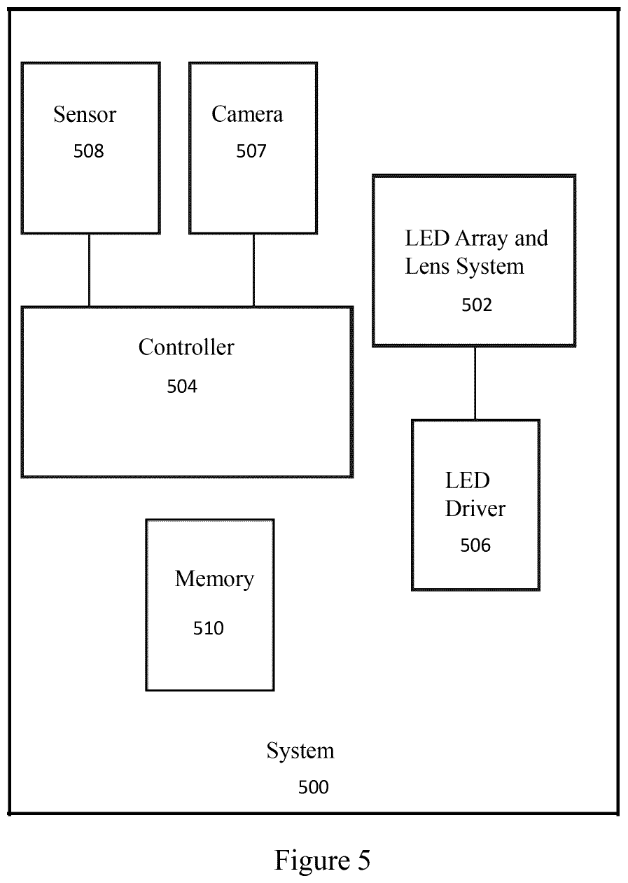

FIG. 5 schematically illustrates an example camera flash system 500 comprising an LED array and lens system 502, which may be similar or identical to the systems described above. Flash system 500 also comprises an LED driver 506 that is controlled by a controller 504, such as a microprocessor. Controller 504 may also be coupled to a camera 507 and to sensors 508, and operate in accordance with instructions and profiles stored in memory 510. Camera 507 and adaptive illumination system 502 may be controlled by controller 504 to match their fields of view.

Sensors 508 may include, for example, positional sensors (e.g., a gyroscope and/or accelerometer) and/or other sensors that may be used to determine the position, speed, and orientation of system 500. The signals from the sensors 508 may be supplied to the controller 504 to be used to determine the appropriate course of action of the controller 504 (e.g., which LEDs are currently illuminating a target and which LEDs will be illuminating the target a predetermined amount of time later).

In operation, illumination from some or all pixels of the LED array in 502 may be adjusted—deactivated, operated at full intensity, or operated at an intermediate intensity. Beam focus or steering of light emitted by the LED array in 502 can be performed electronically by activating one or more subsets of the pixels, to permit dynamic adjustment of the beam shape without moving optics or changing the focus of the lens in the lighting apparatus.

As summarized above, this specification discloses LED arrays comprising a grid structure that physically and optically isolates adjacent LEDs or groups of LEDs in the array from each other, and methods of making such arrays.

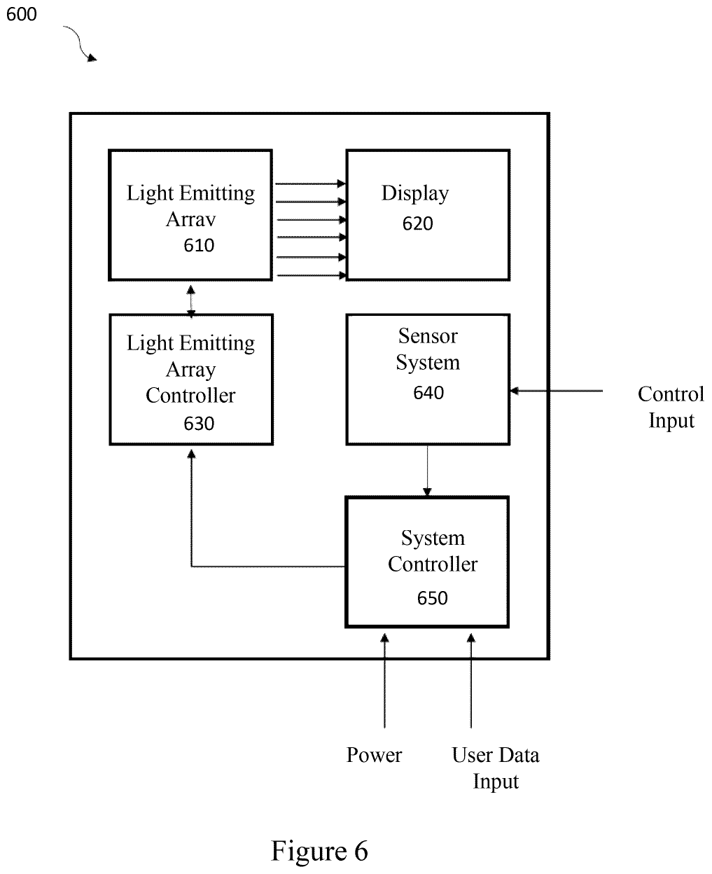

FIG. 6 schematically illustrates an example display (e.g., AR/VR/MR) system 600 that includes an array 610 of individually operable LEDs or pcLEDs, a display 620, a light emitting array controller 630, a sensor system 640, and a system controller 650. Array 610 may be a monolithic array, or comprise one or more monolithic arrays, as described above. The array may be monochromatic. Alternatively, the array may be a multicolor array in which different LEDs or pcLEDs in the array are configured to emit different colors of light, as described above. The array may therefore be or comprise a monolithic multicolor matrix of individually operable LED or pcLED light emitters, which may for example be microLEDs as described above. A single individually operable LED or pcLED or a group of adjacent such LEDs or pcLEDs in the array may correspond to a single pixel (picture element) in the display. For example, a group of three individually operable adjacent LEDs or pcLEDs comprising a red emitter, a blue emitter, and a green emitter may correspond to a single color-tunable pixel in the display. Array 610 can be used to project light in graphical or object patterns that can support AR/VR/MR systems

Control input is provided to the sensor system 640, while power and user data input is provided to the system controller 650. In some embodiments modules included in system 600 can be compactly arranged in a single structure, or one or more elements can be separately mounted and connected via wireless or wired communication. For example, array 610, display 620, and sensor system 640 can be mounted on a headset or glasses, with the light emitting array controller and/or system controller 650 separately mounted.

System 600 can incorporate a wide range of optics (not shown) to couple light emitted by array 610 into display 620. Any suitable optics may be used for this purpose.

Sensor system 640 can include, for example, external sensors such as cameras, depth sensors, or audio sensors that monitor the environment, and internal sensors such as accelerometers or two or three axis gyroscopes that monitor an AR/VR/MR headset position. Other sensors can include but are not limited to air pressure, stress sensors, temperature sensors, or any other suitable sensors needed for local or remote environmental monitoring. In some embodiments, control input can include detected touch or taps, gestural input, or control based on headset or display position.

In response to data from sensor system 640, system controller 650 can send images or instructions to the light emitting array controller 630. Changes or modification to the images or instructions can also be made by user data input, or automated data input as needed. User data input can include but is not limited to that provided by audio instructions, haptic feedback, eye or pupil positioning, or connected keyboard, mouse, or game controller.

Systems and structures described above that emit light through a transparent window or substrate are often subject to light exposure themselves. Certain internal elements in these light emitting structures may degrade as a result of light exposure to certain wavelengths of light.

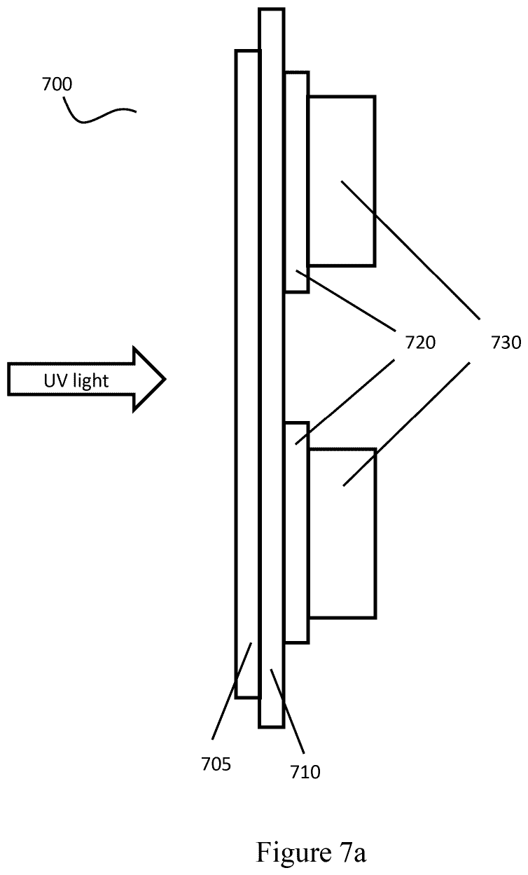

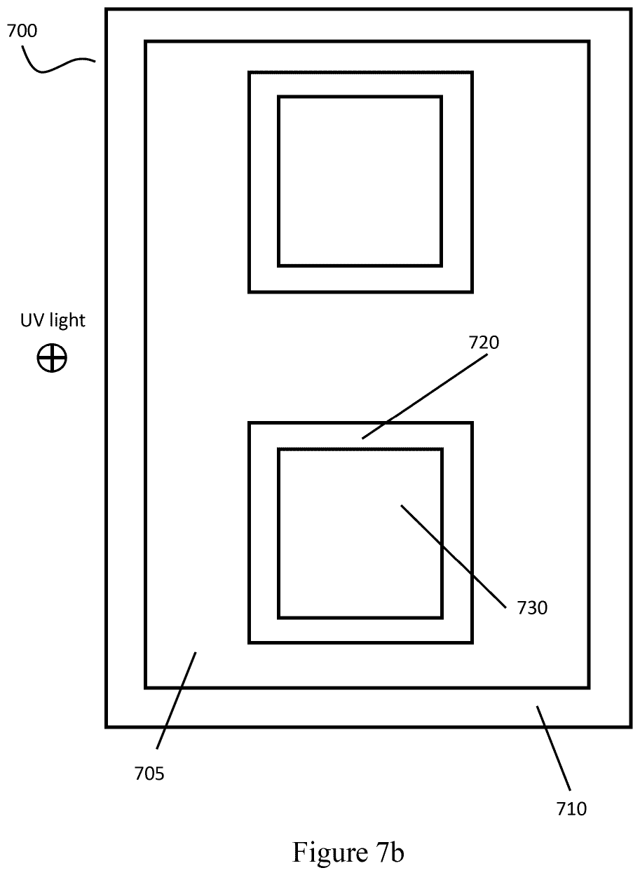

FIGS. 7a and 7b depict a light emitting structure 700 including a transparent UV absorbing layer 705, a substrate 710, and an adhesive layer 720 attaching an array of LEDs 730 to the substrate 710. The substrate 710 may include circuitry that is electrically connected to the array of LEDs 730 to power the LEDs. For example, the substrate 710 may be glass with printed circuitry that is transparent to the human eye. A viewer standing on either side of the light emitting structure 700 (e.g., left or right of the page in FIG. 7a) may be able to clearly view the environment on the respective opposing side of the light emitting structure 700.

The LEDs 730 may be microLEDs, as described above. The array of LEDs 730 may emit light towards the substrate 710 (e.g., to the left of the page in FIG. 7a), or they may emit light away from the substrate 710 (e.g., to the right of the page in FIG. 7a). In the latter case, the light emitting surface may be the same surface as the attachment surface in contact with the adhesive layer 720 bonding the LED 730 to the substrate 710. Alternatively, some of the LEDs 730 in the array may emit light towards the substrate 710 white some of the LEDs 730 may emit light away from the substrate 710, so that light from the light emitting structure 700 is emitted in both directions. As an example, the light emitting structure 700 may be a window of a building, which emits light both towards the occupants on the inside of the building, and towards the pedestrians outside of the building. The LEDs 730 may have different colors from each other, or they may have the same color. At least some or all of the LEDs 730 may emit light of visible color. At least some or all of the LEDs 730 may emit light of an infrared wavelength. Light of an infrared wavelength may be used to track user eye movement, for example determining where the customers inside or outside of a store are looking.

The LEDs 730 are attached to the substrate 710 by an adhesive layer 720. The adhesive layer 720 may comprise discrete regions with gaps separating them so they are not in direct contact with each other. Alternatively, the adhesive layer 720 may be a single continuous sheet such that adhesive regions attaching each individual LED 730 are physically connected to each other. The adhesive layer 720 may be an epoxy-based material using volume contraction to die attach the LEDs 730. Epoxy materials are typically clear and transparent when they are fresh, but are known to degrade over time especially by UV/violet light irradiation. This is especially problematic in outdoor applications or other applications exposed to sunlight. The degradation includes increasing optical blue-absorption known as “yellowing”, and becoming mechanically brittle, or “hardening.” Therefore, light emitting structures using the epoxy are anticipated to possess limited degrees of reliability due to epoxy degradation.

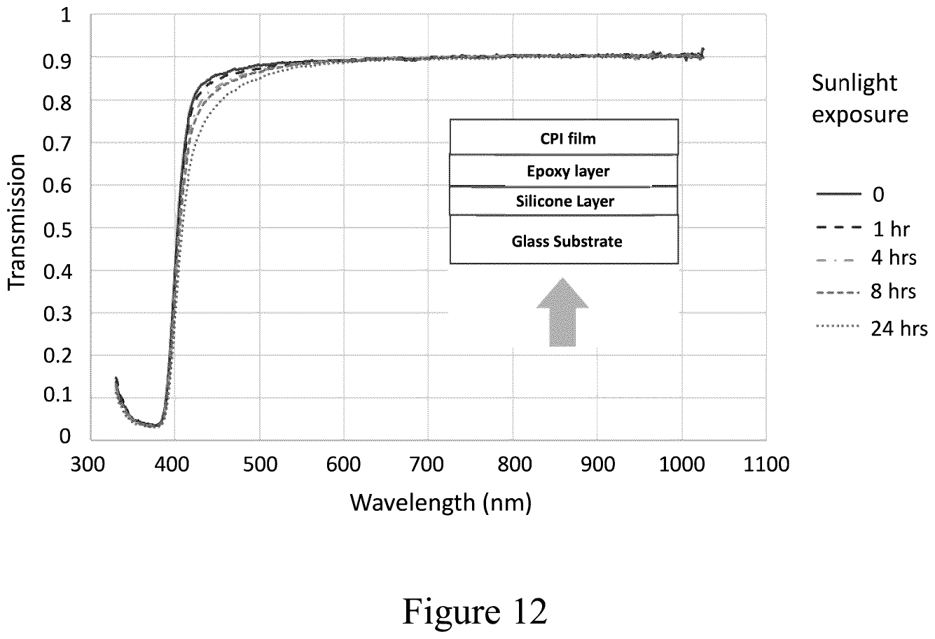

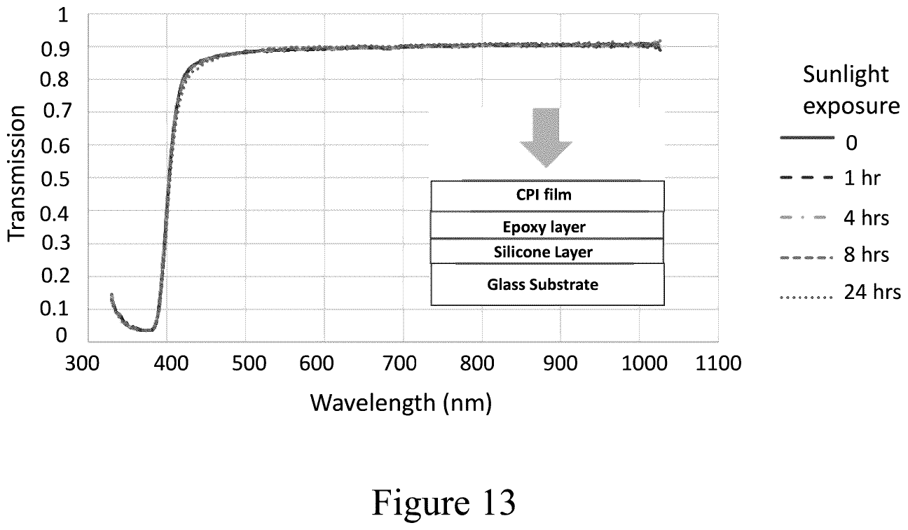

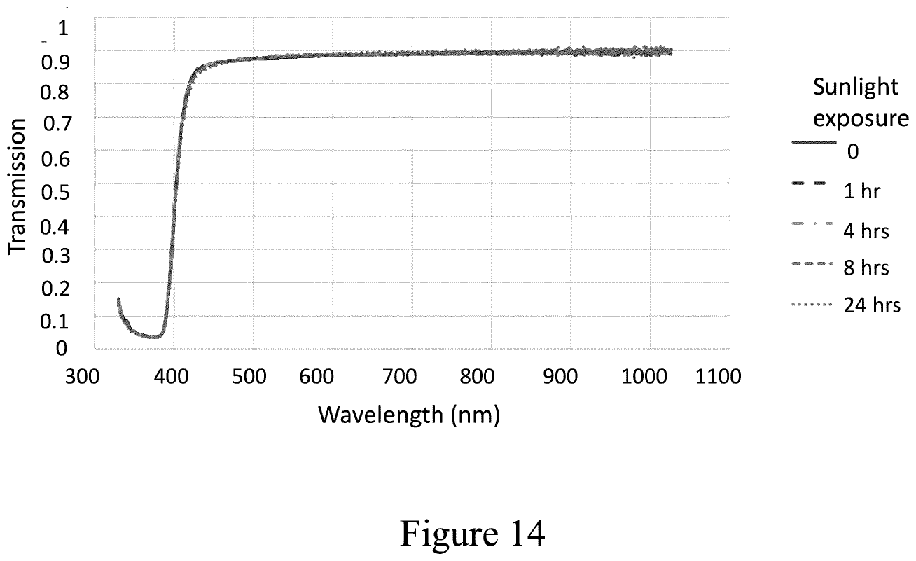

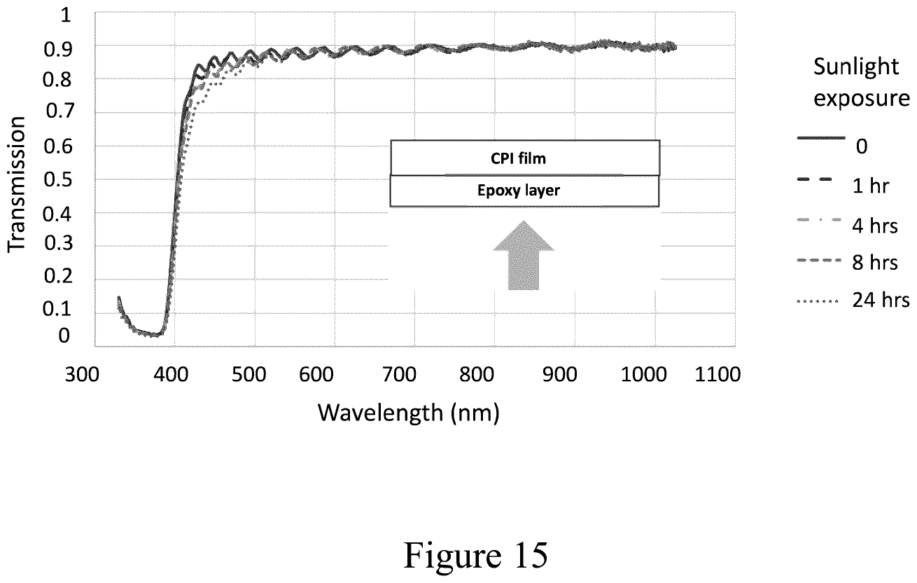

A transparent UV absorbing layer 705 is used to prevent degradation of the adhesive layer 720. The transparent UV absorbing layer 705 may have a high transmission across the visible wavelength range (i.e., is not tinted) while being clear (i.e., is not diffusive) so that any viewers of the display may be able to clearly see the light emitted by the LEDs 730 and/or see through the other side of the light emitting structure 700. The transparent UV absorbing layer 705 may be a clear polyimide (CPI film), which satisfies all of these requirements while being able to block UV radiation to protect the adhesive layer 720. Not all polyimides satisfy the desired characteristics—for example, some polyimides are tinted and do not allow a clear view through the light emitting structure 700. The CPI film may be CP1, Novaclear, or CORIN XLS. The CPI film may have a Yellowness Index (YI) of 2 or less. The CPI film should be transparent or substantially transparent to light in the visible range, blocking and/or absorptive of light in the UV range, and photochemically stable under light exposure, particularly UV exposure. As an example, the CPI film allows less than 50% transmission of light less than 400 nm, e.g., allow less than 20% transmission of light between 300-390 nm, e.g., allow less than 15% transmission of light between 300-390 nm, e.g., allow less than 10% transmission of light between 340-380 nm. FIGS. 12-15 depict experiments done with CPI film, including the layers used and measured for their transmission. In FIG. 12 sunlight comes from a substrate side opposite the CPI film to reach the epoxy layer between. The longer the layers are exposed to sunlight, the more the transmission through the layers in the blue range (around 450 nm) was reduced, showing degradation of the epoxy layer. However, in FIG. 13 sunlight comes from the CPI film side, and there is significantly less reduction of transmission in the blue range. FIG. 14 depicts that the transmission of a CPI film alone was relatively unchanged by sunlight exposure—showing that the CPI film is photochemically stable—and shows the fact that the CPI film absorbs UV light (wavelengths below around 400 nm) while transmitting most visible light. FIG. 15 shows a similar result to FIG. 12, where transmission of epoxy-on-CPI sample in the blue range (around 450 nm) was reduced when sunlight was incident from the epoxy side.

Referring back to FIG. 7a, the light emitting structure 700 may depict, as an example, a window that separates the outside on the left of the page from the inside on the right of the page. In this configuration all, substantially all, or most of the UV light impacting the light emitting structure 700 comes from the left. The transparent UV absorbing layer 705 blocks all, substantially all, or most of the UV light before it reaches the adhesive layer 720 and/or substrate 710. In this way the transparent UV absorbing layer 705 prevents degradation of the adhesive layer 720 from UV light. Because it is transparent or substantially transparent to visible light, a viewer on either side of the transparent UV absorbing layer 705 may still have a clear view through the light emitting structure 700. In FIG. 7a the UV light is depicted by an arrow travelling in a horizontal direction and the substrate 710 may be and/or comprise a plane extending in a vertical direction (running from the top to the bottom of the page) perpendicular to the horizontal direction and extending in a first direction (going into the page) perpendicular to the vertical direction and the horizontal direction. The transparent UV absorbing layer 705 and the adhesive layer 720 may likewise be and/or comprise such planes. The transparent UV absorbing layer 705 is depicted to cover less area than the substrate 710, where area is considered by viewing the light emitting structure 700 from the horizontal direction of FIG. 7a (as depicted in FIG. 7b). However, this is not a requirement, and the transparent UV absorbing layer 705 may be applied to an entire area of the substrate 710. The transparent UV absorbing layer 705 is applied to cover more area than each of the discrete regions of the adhesive layer 720 and/or have a greater height (taken in the vertical direction), taken alone or collectively. However, this is not a requirement, and the transparent UV absorbing layer 705 may have a same area and/or height as the adhesive layer 720. The adhesive layer 720 are depicted to have greater areas and/or heights (in the vertical direction) than the LEDs 730; alternatively, they may have a same or lesser area than the LEDs 730. The transparent UV absorbing layer 705 may be disposed as a continuous sheet, such that the transparent UV absorbing layer 705 covers gaps between the discrete regions of the adhesive layer 720 and gaps between the LEDs 730.

The transparent UV absorbing layer 705 shown in FIG. 7a is disposed on and in direct contact with a first side of the substrate 710. The first side of the substrate 710 is an opposing side from that which the adhesive layer 720 is disposed on and in direct contact with. The transparent UV absorbing layer 705 may be spaced out from the adhesive layer 720 without being in direct contact with them nor in direct contact with the LEDs 730. The transparent UV absorbing layer 705 may be from 0.5-5 mils thick (i.e. 12.7 microns to 127 microns), for example from 1-3 mils thick, for example about or exactly 2 mils thick.

Because all, substantially all, or most of the UV light comes from one side of the light emitting structure 700, for example as sunlight from the outside, the transparent UV absorbing layer 705 need not be disposed on the other side of the light emitting structure 700, which may face the inside of a building from which sunlight does not originate. The transparent UV absorbing layer 705 thus prevents or slows down optical and mechanical degradation of the adhesive layer 720, particularly when the adhesive layer 720 are epoxy-based materials. The transparent UV absorbing layer 705 may be disposed on the substrate 710 by film lamination, spray coating, or other like methods.

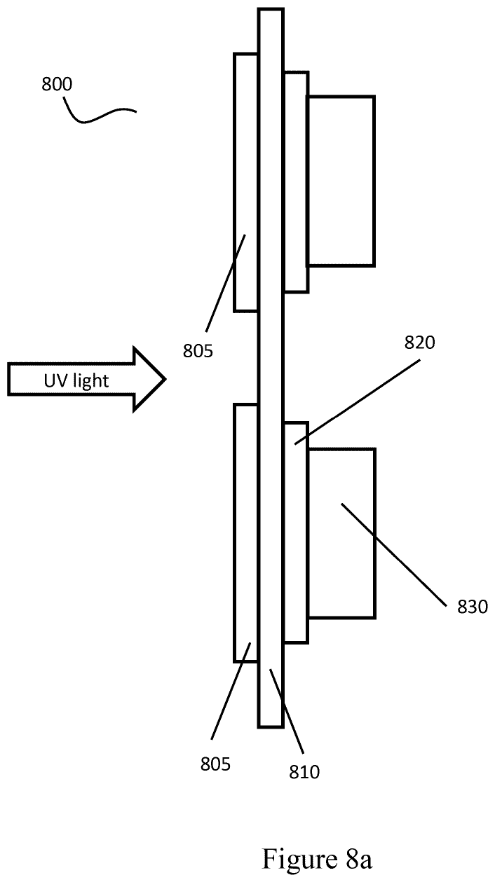

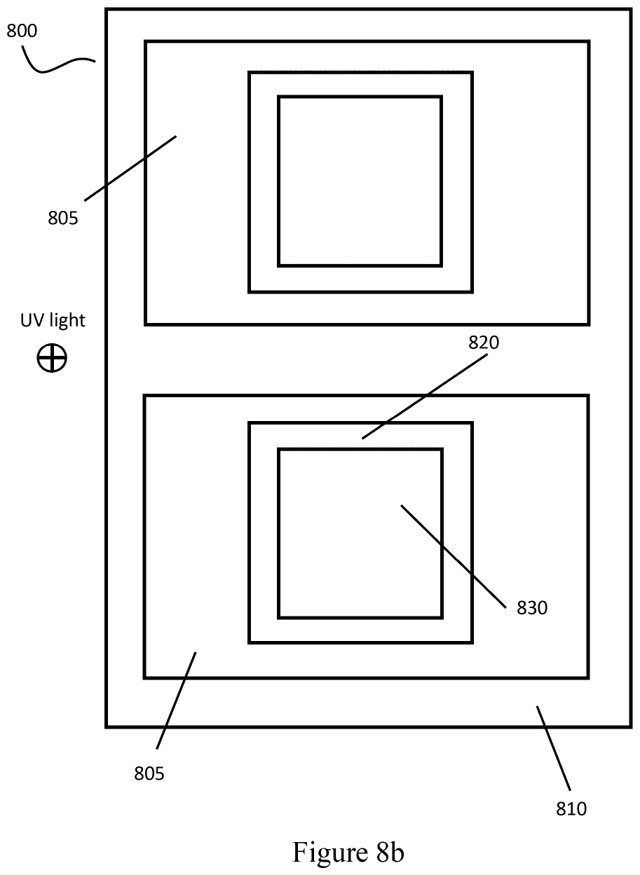

FIGS. 8a and 8b depict a light emitting structure 800 including a transparent UV absorbing layer 805, a substrate 810, and adhesive layers 820 attaching an array of LEDs 830 to the substrate 810. The transparent UV absorbing layer 805 disposed on the substrate 810 comprises multiple separate, discrete regions rather than one continuous sheet or film. Each of the discrete regions may be on the same plane as each other, with attachment surfaces attached to the substrate 810 that are flush with each other and opposing surfaces opposite the attachment surfaces that are flush with each other. There may be one discrete region of the transparent UV absorbing layer 805 for each individual adhesive layer 820 and LED 830. The discrete region of transparent UV absorbing layer 805 may each have a larger area and/or greater height than the respective discrete region of the adhesive layer 820, or the same area and/or same height. The transparent UV absorbing layer 805 may collectively have a lesser area than the substrate 810. The discrete regions of the transparent UV absorbing layer 805 may not be in direct contact with each other.

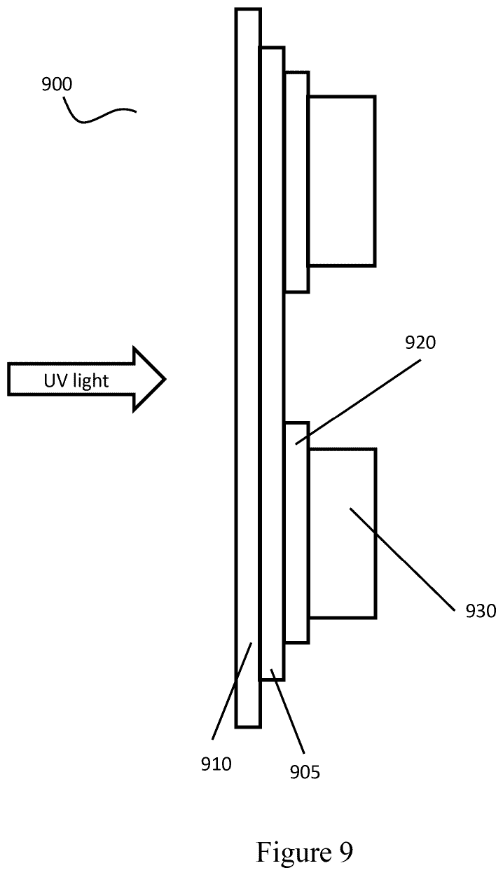

FIGS. 9 depicts a light emitting structure 900 including a transparent UV absorbing layer 905, a substrate 910, and an adhesive layer 920 attaching an array of LEDs 930 to the substrate 910. The transparent UV absorbing layer 905 is disposed on the same side of the substrate 910 as the adhesive layer 920. As a result, the transparent UV absorbing layer 905 may be in direct contact with the adhesive layer 920, which adheres the LEDs 930 to the transparent UV absorbing layer 905. The transparent UV absorbing layer 905 still blocks UV light coming from the substrate side of the light emitting structure 900 before it reaches the adhesive layer 920 and prevents degradation.

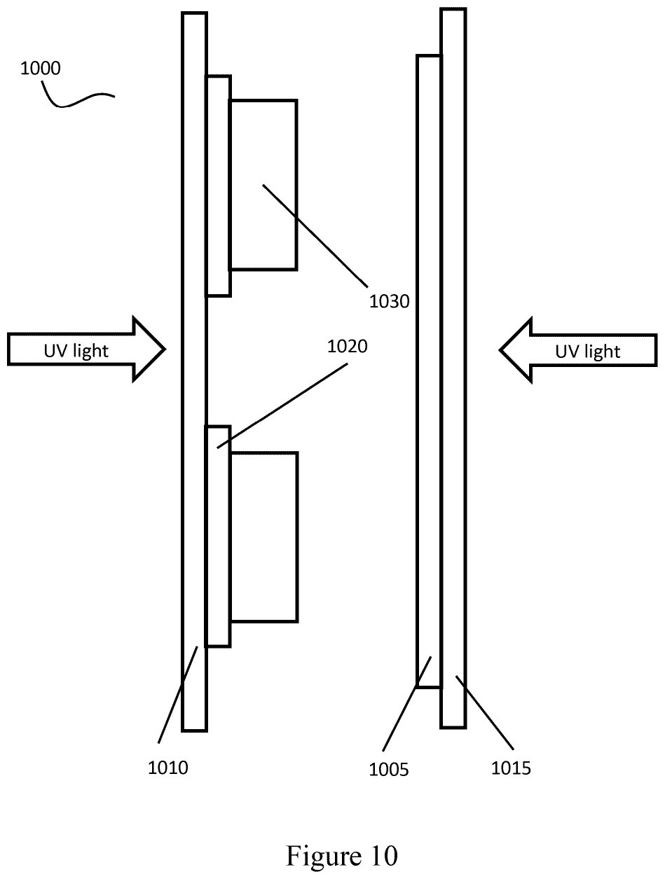

FIG. 10 depicts a light emitting structure 1000 including a transparent UV absorbing layer 1005, a transparent window 1015, a substrate 1010, and an adhesive layer 1020 attaching an array of LEDs 1030 to the substrate 1010. The transparent window 1015 may be disposed on an opposite side of the LEDs 1030 from the substrate 1010. The transparent window 1015 may be transparent to visible light. It may also transmit all, substantially all, or some amount of UV light incident on it. The substrate 1010 may comprise circuitry electrically connected to the LEDs 1030, but it may be opaque rather than transparent, such that it blocks UV light coming in the horizontal direction from the substrate side (i.e., coming from the left side of the page in FIG. 10) from reaching the adhesive layer 1020. Thus, there is no transparent UV absorbing layer 1015 disposed on the side of the LEDs 1030 facing the substrate to intercept any UV rays, since the opaque substrate 1010 blocks the UV light from that side. The substrate 1010 may also be opaque to visible light.

The transparent UV absorbing layer 1005 is disposed to be in direct contact with the transparent window 1015 without being in direct contact with the substrate 1010. The transparent UV absorbing layer 1005 prevents UV light incident from the window side of the light emitting structure 1000 (coming from the right side of the page in FIG. 10) from reaching the adhesive layer 1020. The transparent UV absorbing layer 1005 is depicted as being on the side of the transparent window 1050 facing the LEDs 1030. Alternatively, the transparent UV absorbing layer 1005 may be disposed on the opposite side of the transparent window 1050. The transparent UV absorbing layer 1005 may have a lesser area than the transparent window 1050, or it may have a same area. The transparent UV absorbing layer 1005 may be disposed on the transparent window 1050 by lamination, spray coating, or other like methods. The transparent UV absorbing layer 1005 may be spaced apart from the LEDs 1030, or may be in direct contact with the LEDs 1030.

In embodiments of the invention, FIG. 10 may depict a display of a phone, where the transparent window 1015 and the substrate 1010 may completely encase the array of LEDs 1030 which a user views through the transparent window 1015. The substrate 1010 is opaque, but a user using the phone outside may still expose the display to UV light through the transparent window 1015. The inclusion of the transparent UV absorbing layer 1005 on the transparent window 1015 prevents UV light from reaching the array of LEDs 1030 and the adhesive 1020 which attaches them to the substrate 1010. In this way, degradation of the adhesive 1020 by UV light is prevented, while at the light emitted from the LEDs 1030 is clearly transmitted through the transparent window 1015 and the transparent UV absorbing layer 1005. FIG. 10 may also depict a high-mount signage stop lamp, with an opaque back and a light emitting window at least somewhat transparent to UV light.

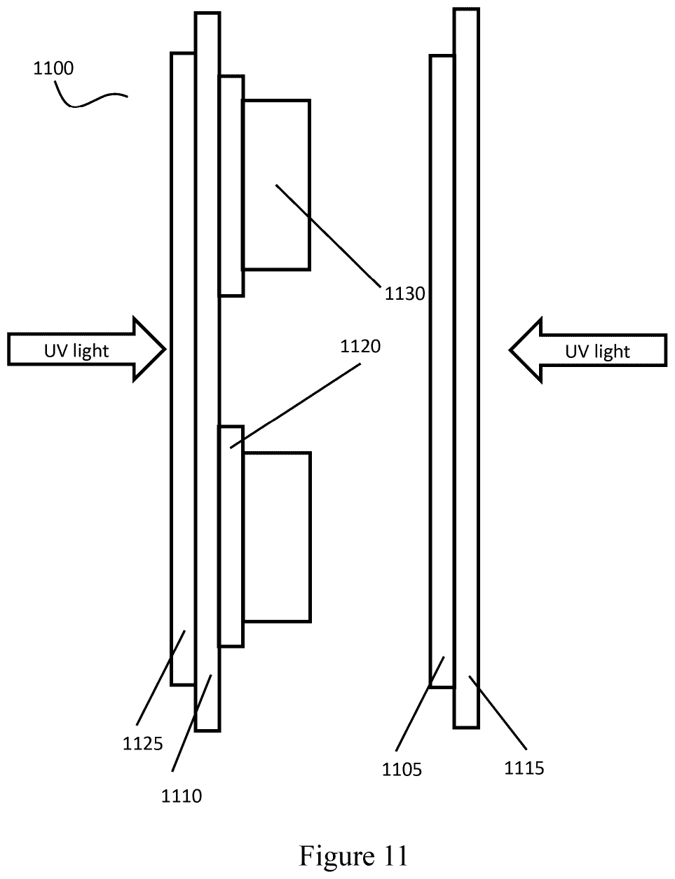

FIG. 11 depicts a light emitting structure 1100 including a first transparent UV absorbing layer 1105 on a transparent window 1115, a second transparent UV absorbing layer 1125 on substrate 1010, and an adhesive layer 1120 attaching an array of LEDs 1030 to the substrate 1110. The substrate 1110 may be transparent to UV light, so that the second transparent UV absorbing layer 1125 may be disposed in the same way(s) as shown in FIG. 7, e.g., directly in contact with the substrate 1110. In this way the adhesive 1120 is protected from UV light from both sides of the light emitting structure 1100. The first and second transparent UV absorbing layer 1105 may have a same area and/or height as each other or different, and may be the same material or different. Other configurations where the first and second transparent UV absorbing layer 1105 and 1115 sandwich the adhesive layer 1120 and/or the LEDs 1130 may be used.

Each of the above configurations of FIGS. 1-11 may be used in any situation where the LEDs and/or adhesive is exposed to UV light, such as for example on automotive glass, automotive center high-mount signage stop lamps, watch and cellphone displays, store signage on windows, or eyeglasses worn on the head (e.g., where the LEDs are populated on the lens of the eyeglasses in a direct view configuration).

This disclosure is illustrative and not limiting. Further modifications will be apparent to one skilled in the art in light of this disclosure and are intended to fall within the scope of the appended claims.

1. A light emitting structure comprising:
a substrate extending in a first direction;
a plurality of light emitting diodes (LEDs) each comprising a light emitting surface and disposed on the substrate, each of the LEDs configured to emit at least one of visible and infrared light;
an adhesive layer attaching the LEDs to the substrate;
a transparent ultraviolet (UV) blocking layer disposed on the substrate, the transparent UV blocking layer being photochemically stable under UV exposure and arranged to prevent UV light travelling along a second direction perpendicular to the first direction from reaching the adhesive layer, and transmit visible light travelling along the second direction.

2. The light emitting structure of claim 1, wherein the LEDs are microLEDs.

3. The light emitting structure of claim 1, wherein the substrate comprises glass having printed circuitry.

4. The light emitting structure of claim 1, wherein the adhesive layer comprises discrete regions not in direct contact with each other arranged to attach individual ones of the LEDs to the substrate.

5. The light emitting structure of claim 4, the transparent UV blocking layer comprising discrete regions not in direct contact with each other arranged to prevent UV light travelling from the second direction from reaching respective ones of the discrete regions of the adhesive layer.

6. The light emitting structure of claim 4, wherein the discrete regions of the transparent UV blocking layer each have greater area than the discrete regions of the adhesive layers.

7. The light emitting structure of claim 4, wherein the discrete regions of the adhesive layer each have greater area than each of the LEDs.

8. The light emitting structure of any of claims 1, wherein the transparent UV blocking layer is in direct contact with the substrate.

9. The light emitting structure of any of claims 1, wherein the transparent UV blocking layer is disposed on an opposite surface of the substrate as the adhesive layer.

10. The light emitting structure of any of claims 1, wherein the transparent UV blocking layer is disposed on same side of the substrate as the adhesive layer.

11. The light emitting structure of any of claims 1, wherein the transparent UV blocking layer is or comprises polyimide.

12. The light emitting structure of any of claims 1, wherein the transparent UV blocking layer has 15% or less transmission of light at wavelengths from 330-390 nm.

13. The light emitting structure of any of claims 1, wherein the transparent UV blocking layer has 80% or greater transmission of light at wavelengths from 420-1000 nm.

14. The light emitting structure of any of claims 1, wherein the transparent adhesive layer is in direct contact with the substrate.

15. A method for making a light emitting diode array, the method comprising:
attaching an array of light emitting diodes (LEDs) on a substrate by an adhesive layer disposed on the substrate, the substrate extending in a first direction, each of the LEDs configured to emit at least one of visible and infrared light;
laminating or spray coating a transparent ultraviolet (UV) blocking layer on the substrate, the transparent UV blocking layer being photochemically stable under UV exposure and arranged to prevent UV light travelling along a second direction perpendicular to the first direction from reaching the adhesive layer, and transmit visible light travelling along the second direction.
